(19) United States
(12) Patent Application Publication
(10) Pub. No.: US 2025/0087573 A1
(43) Pub. Date: Mar. 13, 2025

(54) METHOD AND MATERIAL SYSTEM FOR TUNABLE HYBRID BOND INTERCONNECT RESISTANCE

(71) Applicant: Applied Materials, Inc., Santa Clara, CA (US)

(72) Inventors: Tyler Sherwood, Fonda, NY (US); Raghav Sreenivasan, Fremont, CA (US); Michael Chudzik, Mountain View, CA (US); Maria Gorchichko, Santa Clara, CA (US)

(73) Assignee: Applied Materials, Inc., Santa Clara, CA (US)

(21) Appl. No.: 18/464,926

(22) Filed: Sep. 11, 2023

(51) Int. Cl. H01L 23/498; H01L 21/48; H01L 23/48; H01L 23/64

(52) U.S. Cl. CPC H01L 23/49838; H01L 21/486; H01L 23/481; H01L 23/647

(57) ABSTRACT

The interconnect resistances in a hybrid bonded structure can be controlled and designed. The resistance of each interconnect can be controlled by the width of the vias, the number of vias, and the thickness of liners within the vias. A first interconnect and a second interconnect of a hybrid bonded structure can have different interconnect resistances despite being on the same wafer or chip. The techniques described herein include designing interconnects and forming interconnects with particular resistances.

### TECHNICAL FIELD

The present technology relates to semiconductor systems, processes, and equipment. More specifically, the present technology relates to processes and semiconductor devices for hybrid bonding.

### BACKGROUND

Hybrid bonding (which can also be referred to as heterogeneous integration) is a semiconductor fabrication technique that allows for increased miniaturization of three-dimensional semiconductor device fabrication processes related to advanced node technologies requiring heterogenous integration. Hybrid bonding involves the creation of strong bonds between dies, wafers, and/or substrates without the need for adhesives or separate interconnect materials. However, each interconnect between the wafers may have different resistance requirements. As designs using hybrid bonding require more precise control of both individual and total interconnect resistance, standard hybrid bonding techniques and systems may be incapable of providing precise control of interconnect resistance.

Thus, there is a need for improved systems and methods that can be used to improve precision control of interconnect resistance for semiconductor fabrication techniques that use hybrid bonding. These and other needs are addressed by the present technology.

### SUMMARY

In some embodiments, a method may include identifying a first interconnect of a plurality of interconnects between a first substrate and a second substrate, wherein the first substrate is configured to be hybrid bonded to the second substrate; receiving a first target resistance for the first interconnect; and determining a first design for the first interconnect such that the first interconnect has an actual resistance less than or equal to the first target resistance, wherein determining the first design for the first interconnect may include: determining a first number of vias for the first interconnect, wherein the first number of vias connect a first contact pad of the first substrate to a second contact pad of the second substrate when the first substrate is hybrid bonded to the second substrate.

In some embodiments, a method of forming a semiconductor device may include determining a first target resistance for a first interconnect between a first structure and a second structure; determining a second target resistance for a second interconnect between the first structure and the second structure; forming the first structure, wherein forming the first structure may include: forming a metal layer over a substrate; forming a dielectric layer over the metal layer; etching a first number of vias of the first interconnect in the dielectric layer, wherein the first number of vias is based on the first target resistance, wherein each via of the first number of vias extends from a top surface of the dielectric layer down to a first contact pad of the metal layer; and etching a second number of vias of the second interconnect in the dielectric layer, wherein the second number of vias is based on the second target resistance, wherein each via of the second number of vias extends from the top surface of the dielectric layer down to a second contact pad of the metal layer, wherein the first number of vias is different than the second number of vias.

In some embodiments, a semiconductor device may include a first structure, which may include: a metal layer overlaying a substrate; and a dielectric layer overlaying the metal layer and defining a first number of vias and a second number of vias, wherein each via of the first number of vias extends from a top surface of the dielectric layer down to a first contact pad of the metal layer, wherein each via of the second number of vias extends from the top surface of the dielectric layer down to a second contact pad of the metal layer; a second structure, which may include: a second metal layer overlaying a second substrate; and second dielectric layer overlaying the second metal layer and defining a third number of vias in the second dielectric layer and a fourth number of vias in the second dielectric layer, wherein the third number of vias corresponds to the first number of vias, wherein the fourth number of vias corresponds to the second number of vias, wherein each via of the third number of vias extends from a top surface of the second dielectric layer down to a third contact pad of the second metal layer, wherein each via of the fourth number of vias extends from a top surface of the second dielectric layer down to a fourth contact pad of the second metal layer; wherein the dielectric layer of the first structure is hybrid bonded to the second dielectric layer of the second structure, wherein the first number of vias connect to the third number of vias to form the first interconnect with a first resistance, wherein the second number of vias connect to the fourth number of vias to form the second interconnect with a second resistance, wherein the first resistance is different from the second resistance.

In any embodiments, any and all of the following features may be implemented in any combination and without limitation. The first structure of the semiconductor device may include a first liner in the first number of vias, wherein the first liner has a first thickness; and a second liner in the second number of vias, wherein the second liner has a second thickness, wherein the first thickness and the second thickness are different. The first liner may lie between the dielectric layer and a copper-containing material inside the first number of vias. The second liner may lie between the dielectric layer and the copper-containing material inside the second number of vias. The first number of vias may have a first width. The second number of vias may have a second width. The second structure of the semiconductor device may include a third liner in the third number of vias, wherein the third liner has substantially the first thickness; and a fourth liner in the second fourth of vias, wherein the fourth liner has substantially the second thickness. The method may also include: identifying a second interconnect of a plurality of interconnects between the first substrate and the second substrate; receiving a second target resistance for the second interconnect; and determining a second design for the second interconnect such that the second interconnect has an actual resistance less than or equal to the second target resistance, the first target resistance being different than the second target resistance, wherein determining the second design for the second interconnect may include determining a second number of vias for the second interconnect, wherein the second number of vias connect a third contact pad of the first substrate to a fourth contact pad of the second substrate when the first substrate is hybrid bonded to the second substrate. The method may include determining a set of fabrication parameters for fabricating the first interconnect and the second interconnect. The method may also include determining a set of fabrication parameters for fabricating the first substrate and the second substrate. The method may also include contacting the first structure to a second structure, the second structure which may include: a second metal layer overlaying a second substrate; a second dielectric layer overlaying the second metal layer and defining a third number of vias in the second dielectric layer and a fourth number of vias in the second dielectric layer, wherein the third number of vias corresponds to the first number of vias, wherein the fourth number of vias corresponds to the second number of vias, wherein each via of the third number of vias extends from a top surface of the second dielectric layer down to a third contact pad of the second metal layer, wherein each via of the fourth number of vias extends from a top surface of the second dielectric layer down to a fourth contact pad of the second metal layer; and bonding the first structure to the second structure, wherein the dielectric layer of the first structure is hybrid bonded to the second dielectric layer of the second structure, wherein the first number of vias connect to the third number of vias to form the first interconnect, wherein the second number of vias connect to the fourth number of vias to form the second interconnect. Determining the first design for the first interconnect may further include determining a first width for a first via of the first number of vias. Determining the first design for the first interconnect may further include determining a second width for a second via of the first number of vias, wherein the second width is different than the first width. Forming the first structure may further include depositing a first liner in the first number of vias, wherein the first liner has a first thickness; and depositing a second liner in the second number of vias, wherein the second liner has a second thickness, wherein the first thickness and the second thickness are different. Each via of the first number of vias may be substantially the first width. The fabrication parameters may include a length of time forming a liner inside the first number of vias and the second number of vias of the first substrate. The grain size for a metal-containing material to be used in the first interconnect may be substantially the size of each via of the first number of vias. The first thickness may correspond to a first width of the first number of vias. The second thickness may correspond to a second width of the second number of vias. The first number of vias may have a first width based on the first target resistance. The second number of vias may have a second width based on the second target resistance. The fabrication parameters may include a length of time forming a liner inside the first number of vias and the second number of vias of the first substrate.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers that may be included or configured according to some embodiments of the present technology.

FIG. 2 illustrates operations in a semiconductor design method according to some embodiments of the present technology.

FIG. 3 illustrates exemplary schematic cross-sectional views of structures according to some embodiments of the present technology.

FIG. 4 illustrates operations in a semiconductor processing method according to some embodiments of the present technology.

FIGS. 5A-5D illustrate exemplary schematic cross-sectional views of structures in which material layers are included and processed according to some embodiments of the present technology.

### DETAILED DESCRIPTION

Tuning the resistance for each interconnect between a top wafer, chip, or structure hybrid bonded to a bottom wafer, chip, or structure can be used to form semiconductor devices which require more precise and/or accurate interconnect resistance. Each interconnect between the top wafer and the bottom wafer can be precisely and/or accurately tuned by controlling the number of vias at each interconnect, the metal grain size inside each via, and the ratio of liner to metal in each via. The metal grain size inside each via and the ratio of liner to metal in each via can be adjusted by the width of each via.

Conventional hybrid bonding systems are unable to precisely control interconnect resistance. The inability to precisely control interconnect resistance prevents the hybrid bonding fabrication method from being used on more complex chip designs. The techniques described herein enable the precise control of interconnect resistance using the hybrid bonding fabrication method.

Hybrid bonding can involve matching up multiple interconnects between a top wafer, chip, or structure to a bottom wafer, chip, or structure. Each interconnect has a resistance. When designing wafers, chips, and/or structures, chip designers may want to be able to precisely and/or accurately control the resistance of each interconnect. Chip designers may also want to be able to tune each interconnect resistance independently such that a first interconnect can have a first resistance and a second interconnect can have a second resistance. By being able to precisely and/or accurately control the resistance of each interconnect, chip designers are able to more accurately predict chip performance and thus increase fabrication yields for usable wafers, chips, and/or structures. Additionally, precisely and/or accurately controlling interconnect resistance enables more complex chips and designs to be fabricated using hybrid bonding.

As an overview, hybrid bonding is a semiconductor fabrication technique that combines the advantages of both direct bonding and traditional bonding methods. It enables the integration of dissimilar materials at a molecular level, facilitating the development of advanced semiconductor devices with improved performance, functionality, and miniaturization that may not require the use of metal interconnects. Hybrid bonding is particularly helpful for three-dimensional semiconductor device fabrication.

When a system consisting of two wafers (dies, substrates, and the like can also be used) are being bonded together via hybrid bonding, the dielectric layers of the wafers are first treated to create a reactive layer via surface activation. Then the dielectric layers can be contacted to each other to bond, for example by spontaneous hydrophilic oxide-oxide bonding. Once the dielectric layers have been bonded, the metal pads of each wafer will be separated by a dishing gap. The system can then be annealed such that the metal pads of each wafer will thermally expand and connect while the dielectric layers will remain approximately the same size by comparison to the metal. Once the annealing is complete, the wafers have been bonded via hybrid bonding.

Although the remaining disclosure will routinely identify specific hybrid bonding processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

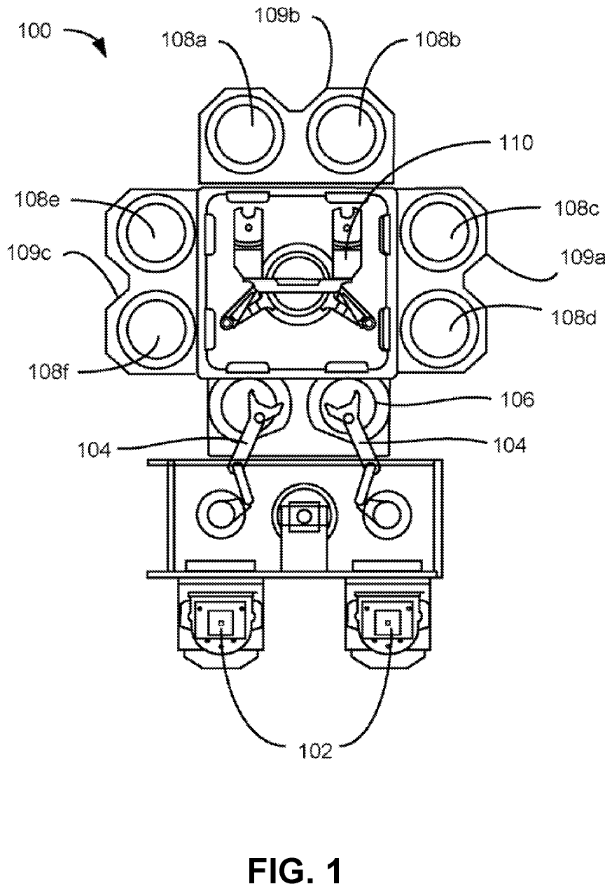

FIG. 1 illustrates a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

System 100, or more specifically chambers incorporated into system 100 or other processing systems, may be used to produce structures according to some embodiments of the present technology.

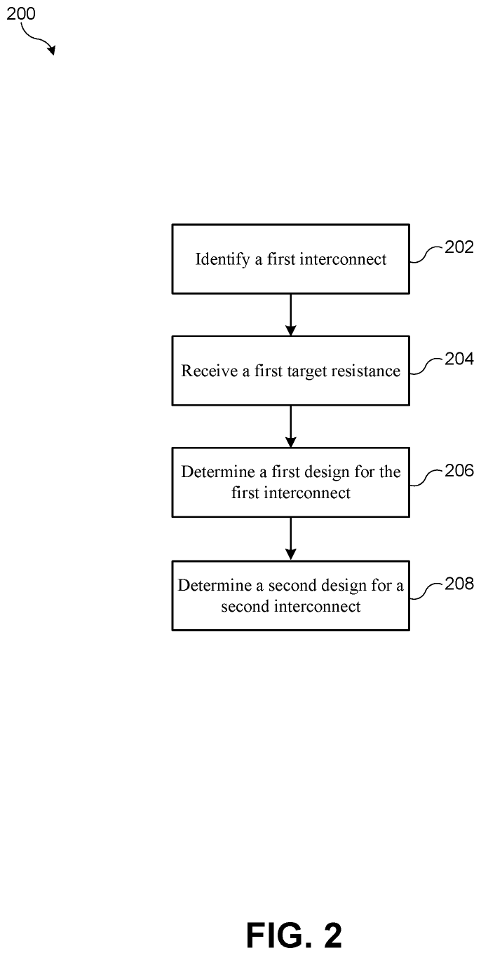

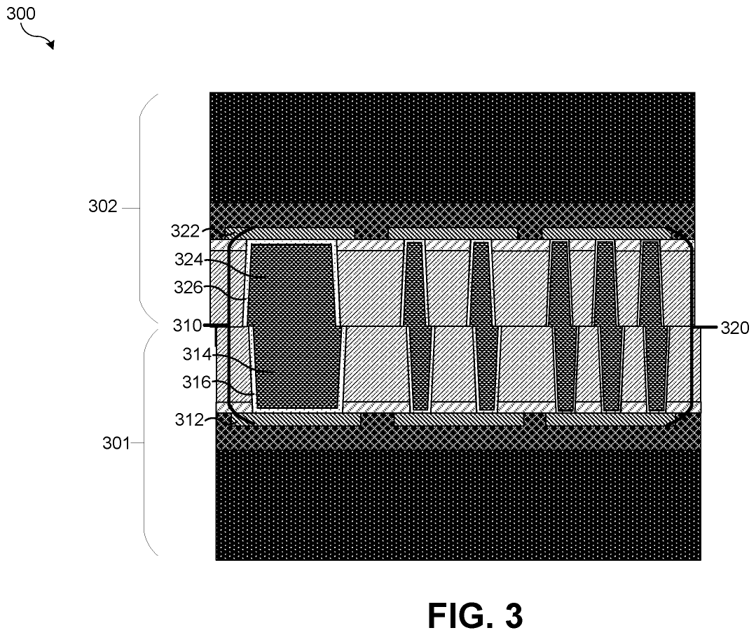

FIG. 2 illustrates a flowchart of exemplary operations in a method 200 of designing and/or controlling the resistance for an interconnect between hybrid bonded structures. for hybrid bonding that allows for the control of resistance for each interconnect according to some embodiments of the present technology. Method 200 may include one or more operations prior to the initiation of the method 200. Method 200 may include a number of optional operations, which may or may not be specifically associated with some embodiments of methods according to embodiments of the present technology. Method 200 may describe operations shown schematically in relation to FIG. 3, the illustrations of which will be described in conjunction with the operations of method 200. It is to be understood that the figures illustrate only partial schematic views, and a substrate 302 may contain any number of additional materials and features having a variety of characteristics and aspects as illustrated in the figures.

It should be appreciated that the specific steps illustrated in FIG. 2 provide particular methods of designing and/or controlling the resistance for an interconnect between hybrid bonded structures according to various embodiments. Other sequences of steps may also be performed according to alternative embodiments. For example, alternative embodiments may perform the steps outlined above in a different order. Moreover, the individual steps illustrated in FIG. 2 may include multiple sub-steps that may be performed in various sequences as appropriate to the individual step. Furthermore, additional steps may be added or removed depending on the particular applications. Many variations, modifications, and alternatives also fall within the scope of this disclosure.

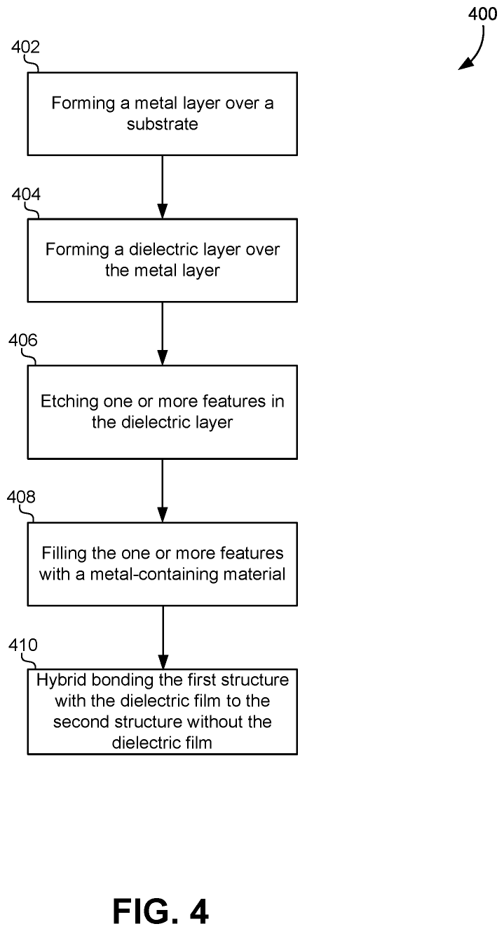

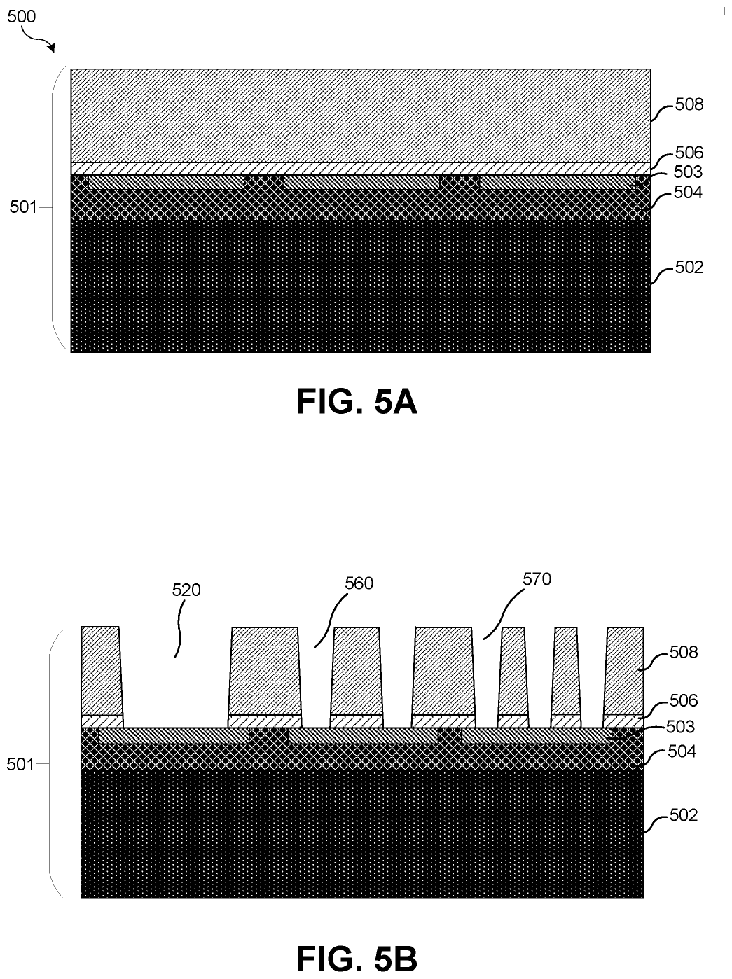

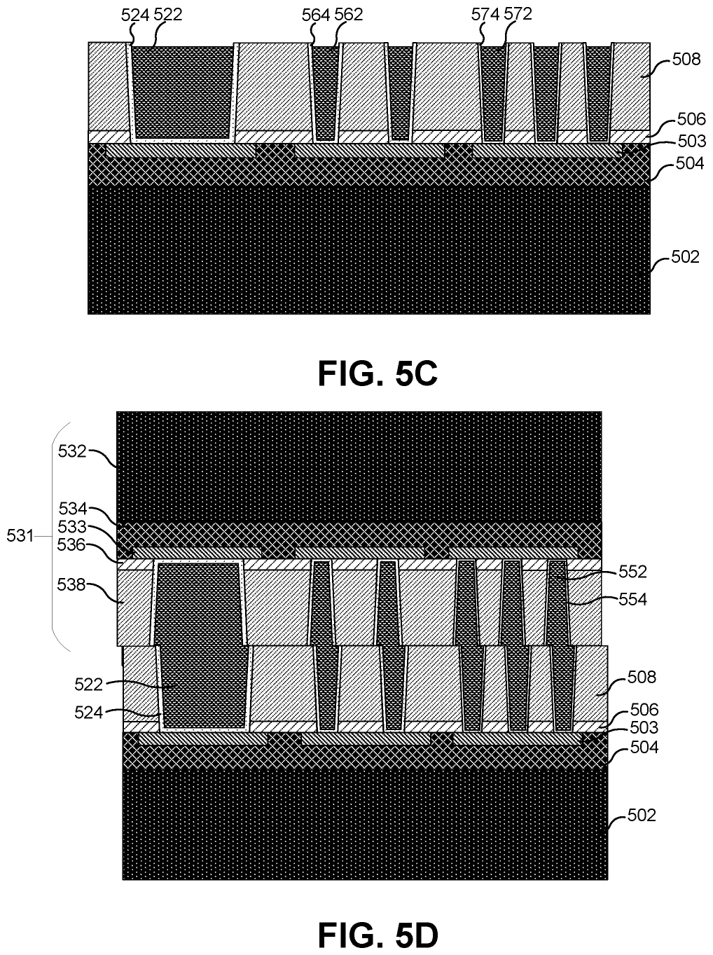

At operation 202, the method of flowchart 200 of designing and/or controlling the resistance for an interconnect between hybrid bonded structures may include identifying a first interconnect. As illustrated in FIG. 3, a design for a hybrid bonded structure 300 includes a first structure 301 being hybrid bonded to a second structure 302. A more detailed description of forming hybrid bonded structure 300, the first structure 301 and the second structure 331 is described below in relation to FIGS. 4, and 5A-5D. Part of designing the hybrid bonded structure 300 can include designing and creating interconnects between the first structure 301 and the second structure 302. A first interconnect 310 can connect a first contact pad 312 of the first structure 301 to a second contact pad 322 of the second structure 302. The first structure 301 can include a first via 314 in a dielectric layer filled with a metal-containing material. The first via 314 can be lined with a liner 316 to separate the metal-containing material from the dielectric layer. Similarly, the second structure 302 can include a second via 324 in a second dielectric layer filled with a metal-containing material. The second via 324 can be lined with a second liner 326 to separate the metal-containing material from the second dielectric layer. Hybrid bonded structures can include multiple interconnects as illustrated in FIG. 3.

At operation 204, the method of flowchart 200 of designing and/or controlling the resistance for an interconnect between hybrid bonded structures may include receiving a first target resistance. The first target resistance can be a target resistance for the first interconnect 310. In some examples, the first target resistance can be an upper limit resistance such that the interconnect needs to be below a resistance. In some examples, the first target resistance can be a lower limit resistance such that the interconnect needs to be above a resistance. In some examples, the first target resistance can be a range such that the interconnect needs to be within the range of resistances.

At operation 206, the method of flowchart 200 of designing and/or controlling the resistance for an interconnect between hybrid bonded structures may include determining a design for a first interconnect. In some examples, the first interconnect 310 can be designed to have a resistance of about or less than the first target resistance. In some examples, the first interconnect 310 can be designed to have a resistance of about or more than the first target resistance. In some examples, the first interconnect 310 can be designed to have a resistance of within a range around the first target resistance. The resistance of an interconnect can be affected in multiple ways. A first factor in the resistance of an interconnect can include the metal grain size of the metal in the interconnect. As the metal grain size increases, the resistance of the interconnect can decrease. The metal grain size of the interconnect can be substantially the width of the interconnect (or the vias making up the interconnect). As such, a wider interconnect will likely have a lower resistance than a smaller interconnect.

A second factor in the resistance of an interconnect can include the number of vias. As the number of vias of equal width in the interconnect increases, the resistance of the interconnect can decrease. In some examples, an interconnect with multiple vias can have vias of different widths. Having multiple vias of different widths in a single interconnect can allow for more precise designs for interconnects.

A third factor in the resistance of an interconnect can include the metal to liner ratio. A thicker liner between the metal in the via and the contact pad can increase the resistance of the interconnect. In some examples, the thickness of the liner between the metal in the via and the contact pad can be a result of the processes for forming the liner in the vias. In some examples, the liner can be formed via chemical vapor deposition. In some examples, the liner can be formed via atomic layer deposition. Some processes for forming the liner can cause the liner to be thicker in wider vias of a substrate than the thinner vias of the same substrate. In some examples, the width of the via can be a factor in the thickness of the liner between the metal-containing material in the via and the contact pad.

In some examples, a wider interconnect such as the first interconnect 310 can have a lower resistance than a second interconnect 320 that includes three thinner vias as shown in FIG. 3. Other factors can also affect the resistance of an interconnect. Other factors can include fabrication parameters for fabricating the first structure and the second structure. Fabrication parameters can affect the thickness of the liner in the vias. For example, the length of time for forming a liner insides the vias can affect the thickness of the vias.

At operation 208, the method of flowchart 200 of designing and/or controlling the resistance for an interconnect between hybrid bonded structures may include determining a second design for a second interconnect. Determining a second design can involve taking into account the design specifications of the first interconnect 310. For example, the fabrication parameters for the first interconnect 310 and the second interconnect 320 can be the same because the first interconnect 310 and the second interconnect 320 are located on the same hybrid bonded structure. For example, the first interconnect 310 and the second interconnect 320 can have the same liner formation process. However, as described above, the thickness of the liner may be different in the first interconnect 310 and the second interconnect 320. The thickness of the liner in the first interconnect 310 and the second interconnect 320 can be determined during the design process. Determining a second design for a second interconnect 320 can include identifying a second interconnect of the hybrid bonded structure 300. Determining a second design for a second interconnect 320 can also include receiving a second target resistance. Determining a second design for a second interconnect 320 can include determining a second number of vias for the second interconnect. Determining a second design for a second interconnect 320 can be done in much the same way as determining a first design. In some examples, the first interconnect 310 and the second interconnect 320 can have different target resistances. In some examples, the first interconnect 310 and the second interconnect 320 can have vias of different widths. In some examples, the first interconnect 310 and the second interconnect 320 can have a different number of vias. In some examples, the first interconnect 310 and the second interconnect 320 can have different thickness of liners.

FIG. 4 illustrates a flowchart of exemplary operations in a method 400 of forming a semiconductor device 500 for hybrid bonding that allows for the control of resistance for each interconnect according to some embodiments of the present technology. The method 400 may be performed in a variety of processing chambers in which the operations may be performed, such as chambers incorporated in the system 100 described above. Method 400 may include one or more operations prior to the initiation of the method 400, including front-end processing, deposition, etching, polishing, cleaning, or any other operations that may be performed prior to the described operations. The methods 400 may include a number of optional operations, which may or may not be specifically associated with some embodiments of methods according to embodiments of the present technology. Method 400 may describe operations shown schematically in FIGS. 5A-5D, the illustrations of which will be described in conjunction with the operations of method 400. It is to be understood that the figures illustrate only partial schematic views, and a substrate 502 may contain any number of additional materials and features having a variety of characteristics and aspects as illustrated in the figures.

It should be appreciated that the specific steps illustrated in FIG. 4 provide particular methods of forming a semiconductor device 500 for hybrid bonding according to various embodiments. Other sequences of steps may also be performed according to alternative embodiments. For example, alternative embodiments may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. Many variations, modifications, and alternatives also fall within the scope of this disclosure.

FIGS. 5A-5D illustrate incremental structures for forming semiconductor device 500 for hybrid bonding, according to some embodiments. The method of flowchart 400 describes operations shown schematically in FIGS. 5A-5D, the illustrations of which will be described in conjunction with the operations of this method. It is to be understood that the figures illustrate only partial schematic views with limited details, and in some embodiments a substrate may contain any number of semiconductor sections having aspects as illustrated in the figures, as well as alternative structural aspects that may still benefit from any of the aspects of the present technology.

At operation 402, the method of flowchart 400 of forming a first structure 501 may include forming a metal layer 504 over a substrate 502. As illustrated in FIG. 5A, the structure 500 may include a substrate 502. The substrate 502 may have a substantially planar surface or an uneven surface in various embodiments. The substrate 502 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. The substrate 426 may have various dimensions, such as 400 mm or 300 mm diameter wafers, as well as rectangular or square panels. The substrate 502 may be disposed within the processing region of the semiconductor processing chamber. Although shown as a planar substrate, it is to be understood that substrate 502 is included merely to represent an underlying structure, which may include any number of layers or features on a wafer or other substrate, and over which structures as described below may be formed.

As illustrated in FIG. 5A, the structure 500 of forming the first structure 501 may include a metal layer 504. The metal layer 504 can include a variety of integrated circuits. For example, the integrated circuits can be created using technologies such as CMOS, NMOS, or any other suitable integrated circuit technology. As such, the metal layer 504 can include various layers of metal, oxide, and semiconductor. Metals used in the metal layer can include copper or any other high conductivity metal. Although this application will regularly discuss copper, it is to be understood that any number of conductive metal materials may be used in embodiments of the present technology, and the present technology should not be limited to any particular conductive metal material. The metal layer 504 can include contact pads 503 that connect vias to the integrated circuits in the metal layer 504.

In some examples, the layers (for example, the substrate 502, the metal layer 504, and other layers described herein such as the barrier film 506, and the dielectric layer 508) described herein can be directly overlaying each other such that the first layer is overlaying the second layer. For example, the metal layer 504 can directly overlay the substrate 502 such that there are no intervening layers. In some examples, the layers described herein can have layers between them. For example, the metal layer 504 can be overlaying an intervening layer which overlays the substrate 502. Furthermore, when forming a layer, any process for forming or depositing material can be used. For example, chemical vapor deposition (CVD) can be used in some examples while atomic layer deposition (ALD) can be used in other examples. Specifics regarding specific layers and/or materials are also described herein.

At operation 404, the method of flowchart 400 of forming the first structure 501 may include forming a dielectric layer 508 over the metal layer 504. As illustrated in FIG. 5A, the dielectric layer 508 may include one or more layers of dielectrics. Example dielectrics can include silicon oxide, tetraethyl orthosilicate (also referred to as TEOS or TeOs), silicon carbon nitride (SiCN), silicon oxynitride (SiON), or any other kind of dielectric. In some examples, the dielectric layer 508 can be TEOS. In some examples, the dielectric layer 508 can be silicon oxide.

In some examples, the first structure 501 can include a barrier film 506 between the dielectric layer 508 and the metal layer 504. A barrier film 506 can have a low dielectric constant in order to reduce the dielectric constant of copper damascene structures in order to achieve faster and more powerful devices. Some barrier films can have a dielectric constant of less than 5 or even lower. Example barrier films include silicon nitride films, and low-k barrier films such as BLOK (a Si—C—H compound) or N-BLOK (a Si—C—H—N compound) developed by Applied Materials. The barrier film 506 can also be referred to as a capping layer for the metal layer 504.

In some examples, the formation of each the dielectric layer 508, the barrier film 506, the metal layer 504, and/or the substrate 502 can be done in different chambers. In some examples, the formation of the dielectric layer 508, the barrier film, the metal layer 504, and/or the substrate 502 can be done in a single chamber.

At operation 406, the method of flowchart 400 of forming the first structure 501 may include etching features in the dielectric layer 508 and the barrier film 506 if applicable. Features etched into the dielectric layer 508 can include trenches, apertures or vias, or any other structure useful in semiconductor processing. As illustrated in FIG. 5B, the structure 500 may include a first via 520, a second via 560, and a third via 570 in the dielectric layer 508. The first via 520, second via 560, and the third via 570 can extend from a top surface of the dielectric layer 508 down to at least a top surface of the metal layer 504. In this way, the first via 520, second via 560, and the third via 570 extend from the top surface of the dielectric layer 508 to contact pads 503. Generally, vias are used to form interconnects when the first structure 501 is hybrid bonded to another structure. As illustrated in FIG. 5B, the first via 520 can be wider than the second via 560. In turn, the second via 560 can be wider than the third via 570. The width of the first via 520, the second via 560, and the third via 570 can be designed (as described in relation to FIGS. 2 and 3 above) to provide different interconnect resistances once the vias are connected to corresponding vias from another structure as described below. Similarly, the number of vias connected to a contact pad can be different in order to control the resistance of an interconnect as described herein. Although only six vias are shown in the figure, it is to be understood that exemplary structures may have any number of features defined along the structure according to embodiments of the present technology.

The etchant used to etch the features into the dielectric layer 508 and barrier film 506 can include a variety of semiconductor processing etches that are either solutions or plasmas, such as chlorine, fluorine, oxygen plasma, or fluorine-and-oxygen. In some examples, the etchants can be applied one at a time. In some examples, multiple etchants can be combined to form a multi-material etch. In some examples, a fluorine etch can be used on a TEOS layer of the dielectric layer 508. In some examples, an ashing etch such as an oxygen plasma can be used to remove organics. In some examples, a fluorine-and-oxygen etch can be used on a BLOK or n-BLOK layer of the dielectric layer 508. In some examples, one or more etches can be dry reactive ion etches. In some examples, one or more etches can be wet etches. Different etchants can have selectivity for different layers such that when an etchant is used it will primarily etch a targeted layer rather than other layers exposed to the etch. For example, a fluorine etch used on a TEOS layer of the dielectric layer 508 may selectively etch the TEOS layer. The selectivity of the etch can make the etching of the targeted layer at a rate that is greater than or about 1.5:1 compared to one or more other layers, and may be greater than or about 1.6:1, greater than or about 1.7:1, greater than or about 1.8:1, greater than or about 1.9:1, greater than or about 2.0:1, greater than or about 2.1:1, greater than or about 2.2:1, greater than or about 2.3:1, greater than or about 2.4:1, greater than or about 2.5:1, greater than or about 2.6:1, greater than or about 2.7:1, greater than or about 2.8:1, greater than or about 2.9:1, greater than or about 3.0:1, or more.

At operation 408, the method of flowchart 400 of forming the first structure 501 may include filling the feature with a metal-containing material. As illustrated in FIG. 5C, the structure 500 may include a metal-containing material 522 in the first via 520. The metal-containing material 522 can be a high conductivity material that can be used as an interconnect between integrated circuits. In some examples, the metal in the metal-containing material 522 includes copper such that the metal-containing material 522 is a copper-containing material. Metals used to fill the feature can include copper or any other high conductivity metal. Although this application will regularly discuss copper, it is to be understood that any number of conductive metal materials may be used in embodiments of the present technology, and the present technology should not be limited to any particular conductive metal material.

In some examples, a liner is formed in the vias prior to filling the vias with the metal-containing material. As illustrated in FIG. 5C, the structure 500 may include a liner 524 in the first via 520 such that the liner lies between the first via 520 in the dielectric layer 508 and the metal-containing material 522. In some embodiments, the liner 524 may be tantalum nitride, or any other suitable liner material incorporated to limit or prevent the potential for diffusion of metal into the dielectric material.

Similarly, a liner 564 can be formed in the second via 560 and a liner 574 can be formed in the third via 570. The thickness of the liner can be related to the width of the via. For example, the second via 560 is thinner (for example, having a smaller width) than the first via 520. Here, the liner 564 can be thinner than the liner 524. Similarly, the liner 574 can be thinner than the liner 564 because the third via 570 is thinner than the second via 560.

In some examples, after the feature has been filled with a metal-containing material 522, the first structure 501 can be polished via a chemical-mechanical polishing (CMP) process. After the first structure 501 has been polished via the CMP process, top surface of the metal-containing material 522 can be recessed in relation to the top surface of the dielectric layer 508, for example as illustrated in FIG. 5C. The CMP process may cause the top surface of the metal-containing material to form a concave shape or dish shape that may feature a nadir or dish depth, respectively, that is the difference in height between the lowest point in the metal and the surface from which the feature is formed in the dielectric material, or a difference in edge height of the metal within the feature. If the nadir or dish depth combined with a recession depth of the top surface of the metal-containing material 522 to the top surface of the dielectric layer 508 (the combination being referred to as combined depth) is too great, the material may not be useful for certain end products. For example, copper-to-copper hybrid bonding is one such application that may be sensitive to an imprecise combined depth. In some applications of copper-to-copper hybrid bonding, if the combined depth is too great, the copper-to-copper bond may not be sufficiently strong due to limited contact with studs from mating features, or the coupling may not occur at all. A combined depth of less than 5 nm may be small enough for copper-to-copper hybrid bonding, for example.

In some examples, the liner 524 can be polished via the CMP process such that the top surface of the liner 524 aligns with the top surface of the dielectric layer 508. In some examples, the liner 524 can be polished via the CMP process such that the top surface of the liner 524 aligns with the top surface of the metal-containing material 522 as seen in FIG. 5C. In some examples, the liner 524 can be polished via the CMP process such that the top surface of the liner 524 is recessed in relation to the top surface of the metal-containing material 522 and protruding in relation to the top surface of the dielectric layer 508.

At operation 410, the method of flowchart 400 may further include bonding the first structure 501 to a second structure 531 via hybrid bonding as shown in FIG. 5D. In some examples, the second structure 531 is similar to the first structure 501 in layout, layers, and materials used. The second structure 531 can include a second metal layer 534 overlaying a second substrate 532. The second metal layer 534 can be similar to the metal layer 504 such that all description of the metal layer 504 is applicable to the second metal layer 534. The second substrate 532 can be similar to the substrate 502 such that all description of the substrate 502 is applicable to the second metal-substrate 532. The second structure 531 can also include a second dielectric layer 538 overlaying the second metal layer 534 and defining a second set of one or more features in the second dielectric layer 538. The second dielectric layer 538 of the second structure 531 can be similar to the dielectric layer 508 of the first structure 501 such that all description of the dielectric layer 508 is applicable to the second dielectric layer 538. In some examples, the second structure 531 can include a second barrier film 536 between the second dielectric layer 538 and the second metal layer 534. The second barrier film 536 can be similar to the barrier film 506 such that all description of the barrier film 506 is applicable to the second barrier film 536. The second structure 531 can include a second metal-containing material 554 deposited within the second set of one or more features. The second metal-containing material 554 can be similar to the metal-containing material 522 such that all description of the metal-containing material 522 is applicable to the second metal-containing material 554. In some examples, the material used for the metal-containing material 522 is the same material used for the second metal-containing material 554. In some examples, the second structure 531 can include second contact pads 533. The second metal-containing material 554 can connect the second contact pads 533 to the metal-containing material 522 and the contact pads 503 in order to form the interconnects between the first structure 501 and the second structure 531. In some examples, the second structure 531 may include a second liner 554 in the second set of one or more features such that the second liner 554 lies between the second set of one or more features in the second dielectric layer 538 and the second metal-containing material 554. The second liner 554 can be similar to the liner 524 such that all description of the liner 524 is applicable to the second liner 554. In some examples, the first structure 501 can be considered to be hybrid-bonded to the second structure 531. In some examples, the dielectric layer 508 can be considered hybrid-bonded to the second dielectric layer 538. In some examples, the metal-containing material 522 can be considered hybrid-bonded to the second metal-containing material 554.

In some examples, bonding the first structure 501 to the second structure 531 can include using a surface activation process on the first structure 501 and/or the second structure 531. The surface activation process can include contacting the first structure 501 and/or the second structure 531 with a hydrogen-containing precursor. The surface activation process can activate the top surface of the dielectric layer 508 of the first structure 501 and/or the top surface of the second dielectric layer 538 of the second structure 531 such that either one or both surfaces have been hydroxylated to have dangling hydroxylation groups. In some examples, water is then applied to the top surface of the dielectric layer 508 of the first structure 501 and/or the top surface of the second dielectric layer 538 of the second structure 531.

The top surface of the dielectric layer 508 of the first structure 501 and the top surface of the second dielectric layer 538 of the second structure 531 can then be aligned and contacted. The top surface of the dielectric layer 508 of the first structure 501 and the top surface of the second dielectric layer 538 of the second structure 531 are aligned to form interconnects between the vias of the first structure 501 and the vias of the second structure 531. When the top surface of the dielectric layer 508 contacts the top surface of the second dielectric layer 538, a spontaneous bonding occurs primarily via Van der Waals bonds to set an initial bond between the top surface of the dielectric layer 508 and the top surface of the second dielectric layer 538.

This causes the first structure 501 and the second structure 531 to be bonded together via the top surface of the dielectric layer 508 contacting the top surface of the second dielectric layer 538. The initial bond between the first structure 501 and the second structure 531 may not be the finalized bond but can be used to keep the first structure 501 and the second structure 531 aligned as additional processes are run to finalize the hybrid bond.

The combination structure of the first structure 501 and the second structure 531 can then annealed. During the annealing operation, the dielectric layer 508 and the second dielectric layer 538 may further form oxide-to-oxide covalent bonds increasing the bond strength between the dielectric layer 508 and the second dielectric layer 538. In some examples, the water and/or the dangling hydroxylation groups assist in forming the oxide-to-oxide covalent bonds between the dielectric layer 508 and the second dielectric layer 538. Once the oxide-to-oxide covalent bonds between the dielectric layer 508 and the second dielectric layer 538 form, the bond between the dielectric layer 508 and the second dielectric layer 538 can be indistinguishable from the bonds within the dielectric layer 508 and/or the second dielectric layer 538.

The annealing of the combination structure can also cause the metal-containing material 522 to extrude towards the second metal-containing material 554. As previously described, the combined depth of the metal-containing material 522 (and the second metal-containing material 554 by extension) is important for the bonding of the metal-containing materials. When the combined depth is less than 5 nm or lower, subsequent annealing to bond the metal-containing material 522 and the second metal-containing material 554 may be effective as the metal-containing material 522 and the second metal-containing material 554 may be close enough to bond to each other during the annealing step of hybrid bonding. During the annealing step, the metal-containing materials from the two structures may extrude towards one another, may contact each other, and may bond. Additionally, during the annealing step (and other steps), the metal grain size of the metal-containing material 522 and the second metal-containing material 554 can grow. At some point prior to the end of the annealing step, the metal grain size of the metal-containing material 522 and the second metal-containing material 554 can be substantially the size of the via containing the metal-containing materials. At reduced annealing temperatures according to some embodiments of the present technology, unless the dishing is sufficiently reduced, the amount of expansion may be insufficient to allow adequate coupling between the copper. By performing polishing operations according to the present technology, reduce dishing may be provided, which may improve coupling capability between substrates at reduced annealing temperatures.

The bonding of the metal-containing material 522 and the second metal-containing material 554 forms interconnects between the first structure 501 and the second structure 531. Each interconnect has a resistance. As described herein, the resistance for each interconnect can be precisely and/or accurately controlled. The resistance of each interconnect can be controlled and/or designed by tuning the width of the vias, the number of vias, and the thickness of the liners within the vias as described herein.

Once the annealing process is completed, the first structure 501 and the second structure 531 are hybrid bonded to form a single semiconductor device or a single structure. The use of hybrid bonding enables the fabrication of complex semiconductor devices from multiple structures and form the interconnects between the structures.

In some examples, the different operations (for example, operations 402, 404, 406, 408, 410) and subparts of different operations can be done in different chambers of system 100. When a substrate is moved from a first chamber to a second chamber, the substrate is moved without exposing the substrate to an external atmosphere. For example, operation 404 for forming a dielectric layer over the metal layer can be done in a different chamber than operations 410 for hybrid bonding two structures. The use of different chambers may be related to different conditions needed for different operations.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A method comprising:
identifying a first interconnect of a plurality of interconnects between a first substrate and a second substrate, wherein the first substrate is configured to be hybrid bonded to the second substrate;
receiving a first target resistance for the first interconnect; and
determining a first design for the first interconnect such that the first 6 interconnect has an actual resistance less than or equal to the first target resistance, wherein determining the first design for the first interconnect comprises:
determining a first number of vias for the first interconnect, wherein the first number of vias connect a first contact pad of the first substrate to a second contact pad of the second substrate when the first substrate is hybrid bonded to the second substrate.

2. The method of claim 1, wherein determining the first design for the first interconnect further comprises:
determining a first width for a first via of the first number of vias.

3. The method of claim 2, wherein determining the first design for the first interconnect further comprises:
determining a second width for a second via of the first number of vias, wherein the second width is different than the first width.

4. The method of claim 2, wherein each via of the first number of vias is substantially the first width.

5. The method of claim 1, further comprising:
identifying a second interconnect of a plurality of interconnects between the first substrate and the second substrate;
receiving a second target resistance for the second interconnect; and
determining a second design for the second interconnect such that the second interconnect has an actual resistance less than or equal to the second target resistance, the first target resistance being different than the second target resistance, wherein determining the second design for the second interconnect comprises:
determining a second number of vias for the second interconnect, wherein the second number of vias connect a third contact pad of the first substrate to a fourth contact pad of the second substrate when the first substrate is hybrid bonded to the second substrate.

6. The method of claim 5, further comprising determining a set of fabrication parameters for fabricating the first interconnect and the second interconnect.

7. The method of claim 6, wherein the fabrication parameters includes a length of time forming a liner inside the first number of vias and the second number of vias of the first substrate.

8. The method of claim 1, wherein a grain size for a metal-containing material to be used in the first interconnect is substantially the size of each via of the first number of vias.

9. A method of forming a semiconductor device, the method comprising:
determining a first target resistance for a first interconnect between a first structure and a second structure;
determining a second target resistance for a second interconnect between the first structure and the second structure;
forming the first structure, wherein forming the first structure comprises:
forming a metal layer over a substrate;
forming a dielectric layer over the metal layer;
etching a first number of vias of the first interconnect in the dielectric layer, wherein the first number of vias is based on the first target resistance, wherein each via of the first number of vias extends from a top surface of the dielectric layer down to a first contact pad of the metal layer; and
etching a second number of vias of the second interconnect in the dielectric layer, wherein the second number of vias is based on the second target resistance, wherein each via of the second number of vias extends from the top surface of the dielectric layer down to a second contact pad of the metal layer, wherein the first number of vias is different than the second number of vias.

10. The method of claim 9, wherein forming the first structure further comprises:
depositing a first liner in the first number of vias, wherein the first liner has a first thickness; and
depositing a second liner in the second number of vias, wherein the second liner has a second thickness, wherein the first thickness and the second thickness are different.

11. The method of claim 10, wherein the first thickness corresponds to a first width of the first number of vias, and wherein the second thickness corresponds to a second width of the second number of vias.

12. The method of claim 9, further comprising:
contacting the first structure to a second structure, the second structure comprising:
a second metal layer overlaying a second substrate;
a second dielectric layer overlaying the second metal layer and defining a third number of vias in the second dielectric layer and a fourth number of vias in the second dielectric layer, wherein the third number of vias corresponds to the first number of vias, wherein the fourth number of vias corresponds to the second number of vias, wherein each via of the third number of vias extends from a top surface of the second dielectric layer down to a third contact pad of the second metal layer, wherein each via of the fourth number of vias extends from a top surface of the second dielectric layer down to a fourth 12 contact pad of the second metal layer; and
bonding the first structure to the second structure, wherein the dielectric layer of the first structure is hybrid bonded to the second dielectric layer of the second structure, wherein the first number of vias connect to the third number of vias to form the first interconnect, wherein the second number of vias connect to the fourth number of vias to form the second interconnect.

13. The method of claim 12, wherein the first number of vias have a first width based on the first target resistance, and wherein the second number of vias have a second width based on the second target resistance.

14. The method of claim 9, further comprising determining a set of fabrication parameters for fabricating the first substrate and the second substrate.

15. The method of claim 14, wherein the fabrication parameters includes a length of time forming a liner inside the first number of vias and the second number of vias of the first substrate.

16. A semiconductor device comprising:
a first structure comprising:
a metal layer overlaying a substrate; and
a dielectric layer overlaying the metal layer and defining a first number of vias and a second number of vias, wherein each via of the first number of vias extends from a top surface of the dielectric layer down to a first contact pad of the metal layer, wherein each via of the second number of vias extends from the top surface of the dielectric layer down to a second contact pad of the metal layer;
a second structure comprising:
a second metal layer overlaying a second substrate; and
a second dielectric layer overlaying the second metal layer and defining a third number of vias in the second dielectric layer and a fourth number of vias in the second dielectric layer, wherein the third number of vias corresponds to the first number of vias, wherein the fourth number of vias corresponds to the second number of vias, wherein each via of the third number of vias extends from a top surface of the second dielectric layer down to a third contact pad of the second metal layer, wherein each via of the fourth number of vias extends from a top surface of the second dielectric layer down to a fourth contact pad of the second metal layer;
wherein the dielectric layer of the first structure is hybrid bonded to the second dielectric layer of the second structure, wherein the first number of vias connect to the third number of vias to form the first interconnect with a first resistance, wherein the second number of vias connect to the fourth number of vias to form the second interconnect with a second resistance, wherein the first resistance is different from the second resistance.

17. The semiconductor device of claim 16, wherein the first number of vias have a first width, and wherein the second number of vias have a second width.

18. The semiconductor device of claim 16, the first structure further comprising:
a first liner in the first number of vias, wherein the first liner has a first thickness; and
a second liner in the second number of vias, wherein the second liner has a second thickness, wherein the first thickness and the second thickness are different.

19. The semiconductor device of claim 18, wherein the first liner lies between the dielectric layer and a copper-containing material inside the first number of vias, and wherein the second liner lies between the dielectric layer and the copper-containing material inside the second number of vias.

20. The semiconductor device of claim 19, the second structure further comprising:
a third liner in the third number of vias, wherein the third liner has substantially the first thickness; and
a fourth liner in the second fourth of vias, wherein the fourth liner has substantially the second thickness.
